(19) United States
(12) Patent Application Publication
(10) Pub. No.: US 2025/0344593 A1
(43) Pub. Date: Nov. 6, 2025

(54) DISPLAY DEVICE

(71) Applicant: Samsung Display Co., LTD., Yongin-si (KR)

(72) Inventor: Gi Na YOO, Yongin-si (KR)

(21) Appl. No.: 18/924,616

(22) Filed: Oct. 23, 2024

(30) Foreign Application Priority Data
May 2, 2024 (KR) 10-2024-0058487

(51) Int. Cl. H10K 59/40; H10K 59/122; H10K 59/131; H10K 59/88

(52) U.S. Cl. CPC H10K 59/40; H10K 59/122; H10K 59/131; H10K 59/88

(57) ABSTRACT

A display device includes a display panel including a display panel including emission areas, and a non-emission area between the emission areas, and a sensing panel above the display panel, and having sensor patterns overlapping the non-emission area and including first sensor patterns extending in a first direction, spaced apart in a second direction crossing the first direction, and having a first width in the second direction, second sensor patterns at a same layer as the first sensor patterns, connected to the first sensor patterns, extending in the second direction, and spaced apart in the first direction, and at least one dummy pattern at a layer that is different from the first and second sensor patterns, and having a second width that is greater than the first width in the second direction.

### CROSS-REFERENCE TO RELATED APPLICATION

The present application claims priority to, and the benefit of, Korean Patent Application No. 10-2024-0058487, filed on May 2, 2024, the disclosure of which in its entirety is herein incorporated by reference.

### BACKGROUND

### 1. Field

The disclosure relates to a display device.

### 2. Description of the Related Art

Recently, as interest in an information display is increased, research and development on a display device is continuously being conducted. For example, the display device is applied to various electronic devices, such as a smartphone, a digital camera, a notebook computer, a navigation system, and a smart television. The display device may be a flat panel display device, such as a liquid crystal display device, a field emission display device, or an organic light-emitting display device.

A recent display device may include a display panel for displaying an image and a sensing panel for sensing an object. At this time, the sensing panel may be used to determine a position of a touch input provided by a user. The sensing panel may be formed through a process separated from the display panel and then combined to the display panel, or may be formed integrally with the display panel through a continuous process.

In a display device in which the sensing panel and the display panel are formed integrally, a problem that external light is reflected on a surface of the display device and a pattern is visible to the user may occur. A method for reducing or minimizing this may be suitable.

The content described above is only intended to help understanding of the background technology of the technical ideas of the disclosure, and therefore, it cannot be understood as a content corresponding to prior art known to those skilled in the art of the disclosure.

### SUMMARY

Embodiments of the disclosure to provide a display device with improved reliability. For example, a display device may improve external light visibility by disposing a dummy pattern at a corresponding position between emission areas.

According to one or more embodiments of the disclosure, a display device includes a display panel including emission areas, and a non-emission area between the emission areas, and a sensing panel above the display panel, and having sensor patterns overlapping the non-emission area and including first sensor patterns extending in a first direction, spaced apart in a second direction crossing the first direction, and having a first width in the second direction, second sensor patterns at a same layer as the first sensor patterns, connected to the first sensor patterns, extending in the second direction, and spaced apart in the first direction, and at least one dummy pattern at a layer that is different from the first and second sensor patterns, and having a second width that is greater than the first width in the second direction.

The display panel may include anode electrodes in the emission areas, and a connection electrode in the non-emission area at a same layer as the anode electrodes, configured to transmit a power voltage, and overlapping the at least one dummy pattern.

The display panel may further include a power line under the connection electrode, configured to provide the power voltage, and electrically connected to the connection electrode, wherein the connection electrode is between the power line and the at least one dummy pattern.

The connection electrode may have a third width that is less than the second width in the second direction.

The third width may be greater than the first width.

The display panel may include a pixel-defining layer partially covering the anode electrodes and the connection electrode, light-emitting layers respectively above the anode electrodes, and a cathode electrode entirely above the pixel-defining layer, the light-emitting layers, and the connection electrode, and electrically connected to the connection electrode and to the light-emitting layers.

The sensor patterns may further include a bridge pattern at a same layer as the at least one dummy pattern, extending in the first direction, and electrically connecting the second sensor patterns to each other.

The at least one dummy pattern may include a first portion protruding from the bridge pattern in the second direction, and a second portion protruding in a direction opposite to the second direction.

The first portion, the second portion, and a portion of the bridge pattern connected to the first and second portions may have the second width in the second direction.

The bridge pattern may have a fourth width that is less than the second width in the second direction.

The bridge pattern may be at a layer that is different from a layer in which the second sensor patterns are located.

The emission areas may include a first column of ones of the emission areas arranged along the second direction, and including a first emission area, a second emission area spaced apart from the first emission area by a first distance in the second direction, and a third emission area spaced apart from the second emission area by a second distance that is greater than the first distance in the second direction, and a second column of others of the emission areas arranged along the second direction, wherein the at least one dummy pattern is between the second and third emission areas in a plan view.

The second column of the others of the emission areas may include a fourth emission area, a fifth emission area spaced apart from the fourth emission area by a third distance in the second direction, and a sixth emission area spaced apart from the fifth emission area by a fourth distance that is less than the third distance in the second direction, wherein the bridge pattern extends in the first direction across the fourth and fifth emission areas, and has the second width between the fourth and fifth emission areas.

The first column of the ones of the emission areas, and the second column of the others of the emission areas, may be configured to emit a same color light.

The at least one dummy pattern may overlap one of the first sensor patterns.

The at least one dummy pattern may be electrically floated.

The second sensor patterns may have a fifth width in the first direction, wherein the at least one dummy pattern has a sixth width that is greater than the fifth width in the first direction.

The fifth width may be substantially equal to the first width.

The emission areas may be arranged in columns defined along a diagonal direction crossing the first and second directions, wherein the at least one dummy pattern is between neighboring ones of the emission areas of the columns.

### BRIEF DESCRIPTION OF THE DRAWINGS

The above and other features of the disclosure will become more apparent by describing in further detail embodiments thereof with reference to the accompanying drawings, in which:

FIG. 1 is a perspective view illustrating one or more embodiments of a display device of the disclosure;

FIG. 2 is a cross-sectional view taken along the line I-I′ of FIG. 1;

FIG. 3 is a cross-sectional view illustrating one or more embodiments of a display panel of FIG. 2;

FIG. 4 is a cross-sectional view illustrating one or more embodiments of a sensing panel of FIG. 2;

FIG. 5 is a block diagram illustrating one or more embodiments of the display device of FIG. 1;

FIG. 6 is a block diagram illustrating one or more embodiments of one of sub-pixels of FIG. 5;

FIG. 7 is a plan view illustrating one or more embodiments of the display panel of the display device of FIG. 1;

FIG. 8 is a plan view illustrating one or more embodiments of the sensing panel of the display device of FIG. 1;

FIG. 9 is an enlarged view illustrating one or more embodiments of portion A of FIG. 8;

FIG. 10 is an enlarged view illustrating one or more embodiments of portion A of FIG. 8 in the display device of FIG. 1;

FIG. 11 is a cross-sectional view taken along the line II-II′ of FIG. 10;

FIG. 12 is a cross-sectional view taken along the line III-III′ of FIG. 10;

FIG. 13 is a cross-sectional view taken along the line IV-IV′ of FIG. 10; and

FIG. 14 is an enlarged view illustrating one or more other embodiments of portion A of FIG. 8.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

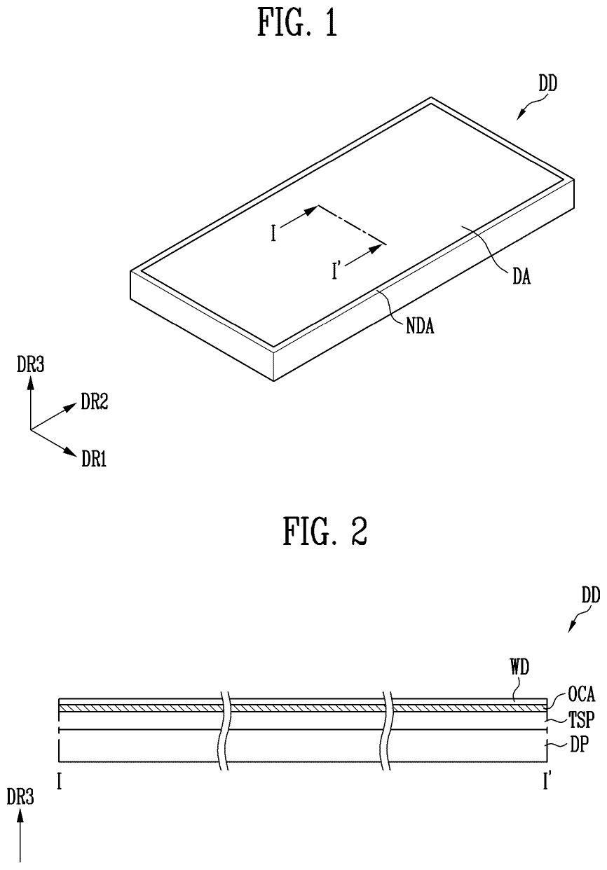

FIG. 1 is a perspective view illustrating one or more embodiments of a display device of the disclosure.

Referring to FIG. 1, when the display device DD is an electronic device in which a display surface is applied to one surface, such as a smartphone, a television, a tablet PC, a mobile phone, a video phone, an e-book reader, a desktop PC, a laptop PC, a netbook computer, a workstation, a server, a PDA, a portable multimedia player (PMP), an MP3 player, a medical device, a camera, or a wearable, the disclosure may be applied to the display device DD.

The display device DD may be provided in various shapes, and for example, the display device DD may be provided in a rectangular plate shape having two pairs of sides parallel to each other, but the disclosure is not limited thereto. When the display device DD is provided in the rectangular plate shape, one pair of sides of the two pairs of sides may be provided longer than the other pair of sides. In the drawing, the display device DD has an angled corner formed of a straight line, but the disclosure is not limited thereto. According to one or more embodiments, the display device DD provided in the rectangular plate shape may have a round shape at a corner where one long side and one short side contact each other.

In one or more embodiments of the disclosure, for convenience of description, the display device DD has the rectangular shape having a pair of long sides and a pair of short sides. At this time, an extension direction of the long side may be indicated as a second direction DR2, an extension direction of the short side may be indicated as a first direction DR1, and a direction perpendicular to the extension directions of the long side and the short side may be indicated as a third direction DR3. The first to third directions DR1 to DR3 may refer to directions indicated by the first to third directions DR1 to DR3, respectively.

In one or more embodiments of the disclosure, at least a portion of the display device DD may have flexibility, and the display device DD may be folded at a portion having flexibility.

The display device DD may include a display area DA displaying an image and a non-display area NDA provided on at least one side of the display area DA. The non-display area NDA may be an area in which an image is not displayed. However, the disclosure is not limited thereto. According to one or more embodiments, a shape of the display area DA and a shape of the non-display area NDA may be relatively designed.

FIG. 2 is a cross-sectional view taken along the line I-I′ of FIG. 1.

Referring to FIG. 2, the display device DD may include a display panel DP, a sensing panel TSP (or a touch sensor), and a window WD.

The display panel DP may display an image through the display area DA (refer to FIG. 1). As the display panel DP, a display panel capable of self-emission, such as an organic light-emitting display panel (OLED panel) using an organic light-emitting diode as a light-emitting element, an ultra-small light-emitting diode display panel (nano-scale LED display panel) using an ultra-small light-emitting diode as a light-emitting element, and a quantum dot organic light-emitting display panel (QD OLED panel) using a quantum dot and an organic light-emitting diode, may be used. In addition, as the display panel DP, a non-emission display panel, such as a liquid crystal display panel (LCD panel), an electro-phoretic display panel (EPD panel), and an electro-wetting display panel (EWD panel), may be used. When the non-emission display panel is used as the display panel DP, the display device DD may include a backlight unit that supplies light to the display panel DP.

The sensing panel TSP may be located on the display panel DP and may receive a touch input of a user. The sensing panel TSP may sense the touch input in a mutual capacitance method or a self-capacitance method.

The window WD for protecting an exposed surface may be provided on the display panel DP and the sensing panel TSP. The window WD may protect the display panel DP and the sensing panel TSP from external shock, and may provide an input surface and/or a display surface to the user. The window WD may be combined with the display panel DP and the sensing panel TSP using an optically transparent adhesive (or bond) member OCA.

The window WD may have a multilayer structure selected from a glass substrate, a plastic film, and/or a plastic substrate. Such a multilayer structure may be formed through a successive process or an adhesion process using an adhesive layer. The entire or a portion of the window WD may have flexibility.

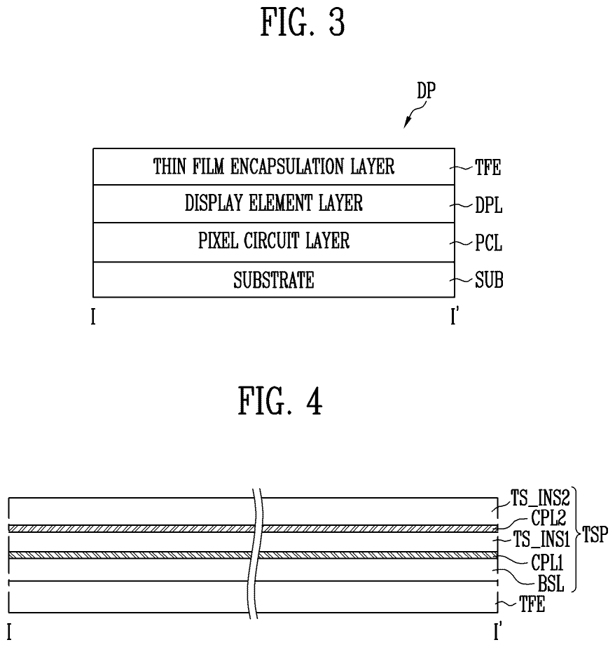

FIG. 3 is a cross-sectional view illustrating one or more embodiments of the display panel of FIG. 2.

Referring to FIG. 3, the display panel DP may include a substrate SUB, a pixel circuit layer PCL, a display element layer DPL, and a thin film encapsulation layer TFE.

The substrate SUB may be a rigid substrate or a flexible substrate. Here, when the substrate SUB is the rigid substrate, the substrate SUB may be one of a glass substrate, a quartz substrate, a glass ceramic substrate, or a crystalline glass substrate. When the substrate SUB is the flexible substrate, the substrate SUB may be one of a film substrate or a plastic substrate including a polymer organic material. In addition, the substrate SUB may include fiber glass reinforced plastic (FRP).

The pixel circuit layer PCL may be located on the substrate SUB. In the pixel circuit layer PCL, a plurality of thin film transistors, and lines connected to the thin film transistors, may be arranged. For example, each thin film transistor may have a shape in which a semiconductor layer, a gate electrode, and a source/drain electrode are sequentially stacked with an insulating layer interposed therebetween. The semiconductor layer may include amorphous silicon, poly silicon, low temperature poly silicon, and an organic semiconductor. The gate electrode and the source/drain electrode may include one of aluminum (AI), copper (Cu), titanium (Ti), or molybdenum (Mo), but the disclosure is not limited thereto. In addition, the pixel circuit layer PCL may include one or more insulating layers.

The display element layer DPL may be located on the pixel circuit layer PCL. The display element layer DPL may include a light-emitting element for emitting light. The light-emitting element may be, for example, an organic light-emitting diode, but the disclosure is not limited thereto. According to one or more embodiments, the light-emitting element may be an inorganic light-emitting element including an inorganic light-emitting material or a light-emitting element (a quantum dot display element) that emits light by changing a wavelength of light emitted using a quantum dot.

The thin film encapsulation layer TFE may be located on the display element layer DPL. The thin film encapsulation layer TFE may be an encapsulation substrate, or may have a shape of an encapsulation layer formed of multiple layers. When the thin film encapsulation layer TFE has the shape of the encapsulation layer, the thin film encapsulation layer TFE may include an inorganic layer and/or an organic layer. For example, the thin film encapsulation layer TFE may have a shape in which an inorganic layer, an organic layer, and an inorganic layer are sequentially stacked. The thin film encapsulation layer TFE may reduce or prevent penetration of external air and moisture into the display element layer DPL and the pixel circuit layer PCL.

FIG. 4 is a cross-sectional view illustrating one or more embodiments of the sensing panel of FIG. 2.

Referring to FIG. 4, the sensing panel TSP (or the touch sensor) may be directly located on a surface on which an image of the display panel DP is emitted to receive a user's touch input and/or a hover input. Here, “directly located” may mean formed by a successive process, excluding attachment using a separate viscosity layer (or adhesive layer). The sensing panel TSP may sense a touch capacitance by contact and/or proximity of a separate input means, such as a user's hand or a conductor similar thereto to recognize the touch input and/or the hover input of the display device DD. Here, the touch input may mean a direct touch (or contact) by the user's hand or the separate input means, and the hover input may mean that the user's hand or the separate input means is near the display device DD including the sensing panel TSP but does not touch the display device DD.

The sensing panel TSP may have a multiple layer structure. The sensing panel TSP may include at least one or more conductive layers, and may include at least one or more insulating layers.

For example, the sensing panel TSP may include a base layer BSL, a first conductive layer CPL1, a first insulating layer TS_INS1, a second conductive layer CPL2, and a second insulating layer TS_INS2.

The first conductive layer CPL1 may be directly located on the thin film encapsulation layer TFE of the display panel DP, but the disclosure is not limited thereto. According to one or more embodiments, another insulating layer, for example, the base layer BSL, may be located between the first conductive layer CPL1 and the thin film encapsulation layer TFE. In this case, the first conductive layer CPL1 may be directly located on the base layer BSL.

Each of the first and second conductive patterns CP1 and CP2 may have a single layer structure or may have a multiple layer structure stacked in a thickness direction. The conductive layer of the single layer structure may include a conductive material. For example, the conductive material may include a metal, such as molybdenum (Mo), silver (Ag), titanium (Ti), copper (Cu), aluminum (Al), or an alloy thereof, or may include transparent conductive oxide, such as indium tin oxide (ITO), indium zinc oxide (IZO), zinc oxide (ZnO), or indium tin zinc oxide (ITZO).

The conductive layer of the multiple layer structure may include metal layers of multiple layers. The metal layers of multiple layers may have, for example, a triple structure of titanium (Ti)/aluminum (Al)/titanium (Ti), but are not limited thereto. The conductive layer of the multiple layer structure may include metal layers of multiple layers and a transparent conductive layer.

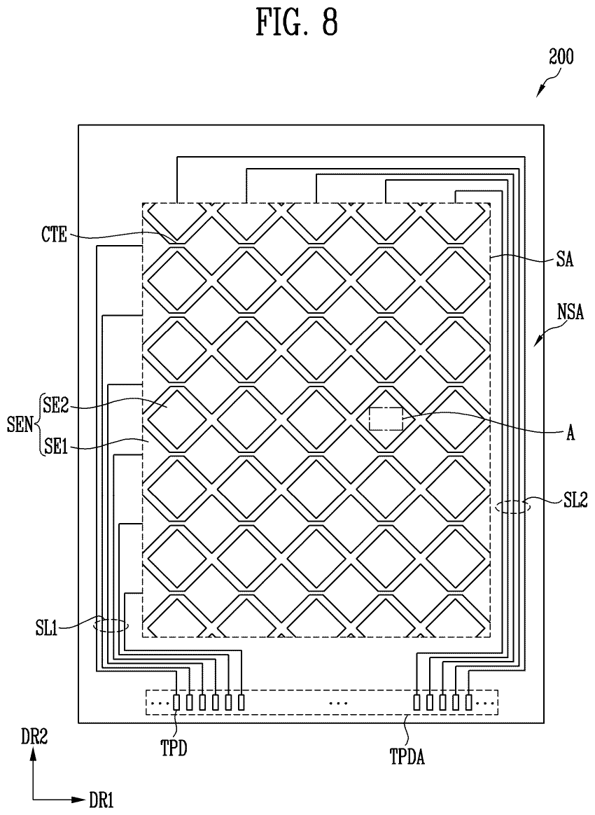

According to one or more embodiments, the first and second conductive layers CPL1 and CPL2 may include sensor electrodes SEN of FIG. 8 and scan lines SL1 and SL2 of FIG. 8.

Each of the first and second insulating layers TS_INS1 and TS_INS2 may include an inorganic material or an organic material. The inorganic material may include at least one of a metal oxide, such as silicon nitride (SiNₓ), silicon oxide (SiOₓ), silicon oxynitride (SiON), or aluminum oxide (AlOₓ). The organic material may include at least one of acryl-based resin, methacryl-based resin, polyisoprene, vinyl-based resin, epoxy-based resin, urethane-based resin, cellulose-based resin, siloxane-based resin, polyimide-based resin, polyamide-based resin, or perylene-based resin.

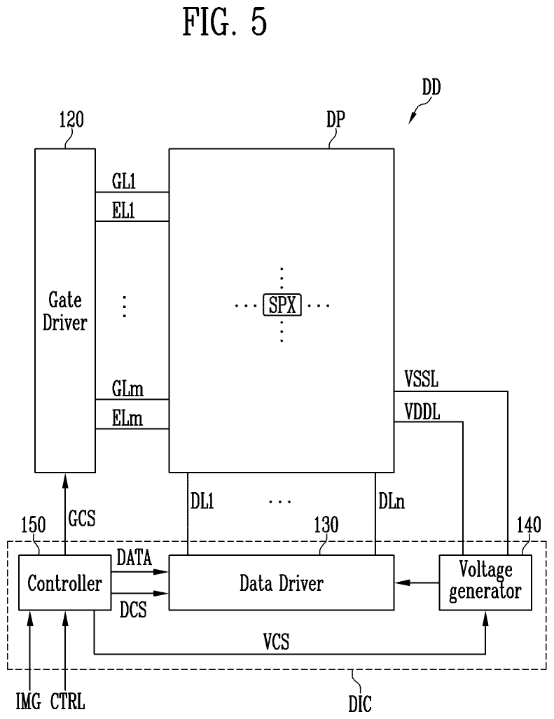

FIG. 5 is a block diagram illustrating one or more embodiments of the display device of FIG. 1.

Referring to FIG. 5, the display device DD may include the display panel DP, a gate driver 120, a data driver 130, a voltage generator 140, and a controller 150.

The display panel DP may include sub-pixels SPX. The sub-pixels SPX may be connected to the gate driver 120 through first to m-th gate lines GL1 to GLm. The sub-pixels SPX may be connected to the data driver 130 through first to n-th data lines DL1 to DLn.

Each of the sub-pixels SPX may include at least one light-emitting element configured to generate light. Accordingly, each of the sub-pixels SPX may generate light of a corresponding color, such as red, green, blue, cyan, magenta, or yellow. Among the sub-pixels SPX, two or more sub-pixels may configure one pixel PXL (not shown). For example, three sub-pixels may configure one pixel PXL.

The gate driver 120 may be connected to the sub-pixels SPX arranged in a row direction through the first to m-th gate lines GL1 to GLm. The gate driver 120 may output gate signals to the first to m-th gate lines GL1 to GLm in response to a gate control signal GCS. In embodiments, the gate control signal GCS may include a start signal indicating a start of each frame, a horizontal synchronization signal for outputting gate signals in synchronization with a timing at which data signals are applied, and the like.

In embodiments, first to m-th emission control lines EL1 to ELm connected to the sub-pixels SPX of the row direction may be further provided. In this case, the gate driver 120 may include an emission control driver configured to control the first to m-th emission control lines EL1 to ELm, and the emission control driver may operate under control of the controller 150.

The gate driver 120 may be located on one side of the display panel DP. However, embodiments are not limited thereto. For example, the gate driver 120 may be divided into two or more physically and/or logically divided drivers, and the drivers may be respectively located on one side of the display panel DP and another side of the display panel DP opposite the one side. As described above, the gate driver 120 may be located around the display panel DP in various shapes according to embodiments.

The data driver 130 may be connected to the sub-pixels SPX arranged in a column direction through the first to n-th data lines DL1 to DLn. The data driver 130 may receive image data DATA and a data control signal DCS from the controller 150. The data driver 130 may operate in response to the data control signal DCS. In embodiments, the data control signal DCS may include a source start pulse, a source shift clock, a source output enable signal, and the like.

The data driver 130 may apply data signals having grayscale voltages corresponding to the image data DATA to the first to n-th data lines DL1 to DLn using voltages from the voltage generator 140. When the gate signal is applied to each of the first to m-th gate lines GL1 to GLm, the data signals corresponding to the image data DATA may be applied to the data lines DL1 to DLn. Accordingly, the corresponding sub-pixels SPX may generate light corresponding to the data signals. Accordingly, an image may be displayed on the display panel DP.

In embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 may be configured to generate a plurality of voltages and provide the generated voltages to components of the display device DD. For example, the voltage generator 140 may be configured to generate the plurality of voltages by receiving an input voltage from an outside of the display device DD, adjusting the received voltage, and regulating the adjusted voltage.

The voltage generator 140 may generate a first power voltage and a second power voltage. The first and second power voltages may be provided to the sub-pixels SPX through first and second power lines VDDL and VSSL, respectively. The first power voltage may have a relatively high voltage level, and the second power voltage may have a voltage level that is lower than the first power voltage VDD. In other embodiments, the first power voltage or the second power voltage may be provided by an outside device of the display device DD.

In addition, the voltage generator 140 may generate various voltages. For example, the voltage generator 140 may generate an initialization voltage applied to the sub-pixels SPX. For example, during a sensing operation for sensing electrical characteristics of transistors and/or light-emitting elements of the sub-pixels SPX, a reference voltage (e.g., predetermined reference voltage) may be applied to the first to n-th data lines DL1 to DLn, and the voltage generator 140 may generate the reference voltage.

The controller 150 may control overall operations of the display device DD. The controller 150 may receive input image data IMG and a control signal CTRL from the outside. The controller 150 may provide the gate control signal GCS, the data control signal DCS, and the voltage control signal VCS in response to the control signal CTRL.

The controller 150 may convert the input image data IMG so that the input image data IMG is suitable for the display device DD or the display panel DP, and may output the image data DATA. In embodiments, the controller 150 may output the image data DATA by aligning the input image data IMG so that the input image data IMG is suitable for the sub-pixels SPX of a row unit.

Two or more components of the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally divided components in one driver integrated circuit DIC. In other embodiments, at least one of the data driver 130, the voltage generator 140, or the controller 150 may be provided as a component distinguished from the driver integrated circuit DIC.

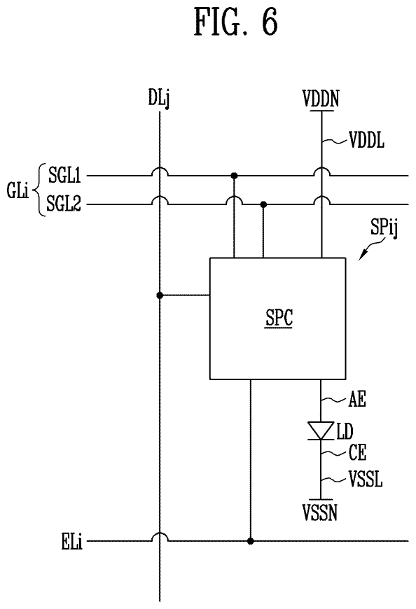

FIG. 6 is a block diagram illustrating one or more embodiments of one of the sub-pixels of FIG. 5.

In FIG. 6, among the sub-pixels SPX of FIG. 5, a sub-pixel SPXij arranged in an i-th row (i is an integer greater than or equal to 1 and less than or equal to m) and a j-th column (j is an integer greater than or equal to 1 and less than or equal to n) is shown as an example.

Referring to FIG. 6, the sub-pixel SPXij may include a sub-pixel circuit SPC and a light-emitting element LD.

The light-emitting element LD may be connected between a first power voltage node VDDN and a second power voltage node VSSN. The power voltage node VDDN may be connected to the first power line VDDL and may receive the first power voltage. The second power voltage node VSSN may be connected to the second power line VSSL and may receive the second power voltage. The first power voltage may have a voltage level that is higher than that of the second power voltage.

The light-emitting element LD may be connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The cathode electrode CE may be connected to the second power voltage node VSSN. The light-emitting element LD may be configured to emit light according to a current flowing from the anode electrode AE to the cathode electrode CE.

The sub-pixel circuit SPC may be connected to an i-th gate line GLi among the first to m-th gate lines GL1 to GLm of FIG. 5, and a j-th data line DLj among the first to n-th data lines DL1 to DLn of FIG. 5. In response to a gate signal received through the i-th gate line GLi, the sub-pixel circuit SPC may control the light-emitting element LD to emit light according to a data signal received through the j-th data line DLj. In embodiments, the sub-pixel circuit SPC may be further connected to the pixel control lines of FIG. 5. In this case, the sub-pixel circuit SPC may control the light-emitting element LD in further response to pixel control signals received through the pixel control lines.

For such operations, the sub-pixel circuit SPC may include circuit elements, for example, transistors and one or more capacitors.

The transistors of the sub-pixel circuit SPC may include P-type transistors and/or N-type transistors. In embodiments, the transistors of the sub-pixel circuit SPC may include a metal oxide silicon field effect transistor (MOSFET). In embodiments, the transistors of the sub-pixel circuit SPC may include an amorphous silicon semiconductor, a monocrystalline silicon, a polycrystalline silicon semiconductor, an oxide semiconductor, and the like.

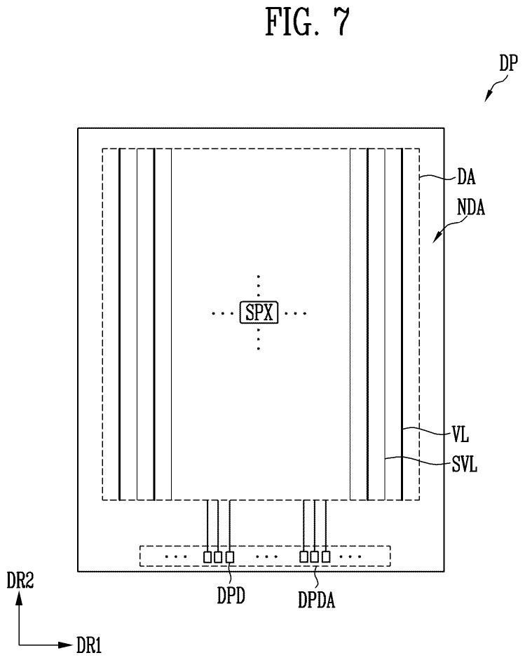

FIG. 7 is a plan view illustrating one or more embodiments of the display panel of the display device of FIG. 1.

Referring to FIG. 7, the display panel DP may include the display area DA and the non-display area NDA.

The display area DA may be an area displaying an image. The display area DA may include a plurality of sub-pixels SPX, a plurality of power lines VL, and a plurality of signal lines SVL.

According to one or more embodiments, the plurality of power lines VL may supply the power voltage received from the voltage generator 140 to the plurality of sub-pixels SPX. Here, the power voltage may be at least one of the first power voltage, the second power voltage, the initialization voltage, or the reference voltage. The plurality of power lines VL may extend in the second direction DR2, and may be spaced apart from each other in the first direction DR1 crossing the second direction DR2.

The plurality of signal lines SVL may supply the data signals received from the data driver 130 to the plurality of sub-pixels SPX. Here, the plurality of signal lines SVL may further include the gate lines GL1 to GLm (refer to FIG. 5) and the emission control lines EL1 to ELm (refer to FIG. 5) in addition to the data lines DL1 to DLn (refer to FIG. 5). The plurality of signal lines SVL may extend in the second direction DR2, and may be spaced apart from each other in the first direction DR1 crossing the second direction DR2.

A display pad area DPDA may be located in the non-display area NDA. The display pad area DPDA may be electrically connected to the sub-pixels SPX of the display area DA through the plurality of signal lines SVL and the plurality of power lines VL. The display pad area DPA may include display pads DPD.

FIG. 8 is a plan view illustrating one or more embodiments of the sensing panel of the display device of FIG. 1.

Referring to FIG. 8, the sensing panel TSP may include a sensor area SA (a sensing area, or an active area) capable of sensing the touch input, and a non-sensor area NSA (or a non-sensing area) surrounding at least a portion of the sensor area SA (e.g., in plan view).

The sensor area SA may be provided in a central area of the sensing panel TSP to overlap the display area DA (refer to FIG. 1). The sensor area SA may have a shape substantially the same as that of the display area DA, but is not limited thereto. Sensor electrodes SEN for sensing the touch input may be provided and/or formed in the sensor area SA.

The non-sensor area NSA may be provided in a peripheral area of the sensing panel TSP to overlap the non-display area NDA, (refer to FIG. 1). Here, the peripheral area may be an area surrounding the central area of the sensing panel TSP (e.g., in plan view). Sensing lines electrically connected to the sensor electrodes SEN to receive and transmit detection a sensing signal may be provided and/or formed in the non-sensing area NSA. In addition, a touch pad area TPDA connected to the sensing lines and electrically connected to the sensor electrodes SEN of the sensor area SA may be located in the non-sensor area NSA. The touch pad area TPDA may include a touch pad TPD. The sensing lines may include a plurality of first sensing lines SL1 and a plurality of second sensing lines SL2.

The sensor electrodes SEN may include a plurality of sensor electrodes SE1 and SE2 and connection electrodes CTE.

The sensor electrodes SEN may include a plurality of first sensor electrodes SE1 and a plurality of second sensor electrodes SE2 electrically insulated from the first sensor electrodes SE1.

The first sensor electrodes SE1 may be arranged in the first direction DR1, and may be electrically connected to adjacent first sensor electrodes SE1 by the connection electrodes CTE to configure at least one sensor row. The second sensor electrodes SE2 may be arranged in the second direction DR2 crossing the first direction DR1, and may be electrically connected to adjacent second sensor electrodes SE2 to form at least one sensor column.

The first and second sensor electrodes SE1 and SE2 may be electrically connected to one touch pad TPD through corresponding sensing lines. As an example, the first sensor electrodes SE1 may be electrically connected to the touch pads TPD through the first sensing lines SL1, and the second sensor electrodes SE2 may be electrically connected to the touch pads TPD through the second sensing lines SL2.

The first sensor electrodes SE1 may be driving electrodes for receiving a driving signal for detecting a touch position in the sensor area SA, and the second sensor electrodes SE2 may be a sensing electrode for outputting a sensing signal for detecting the touch position in the sensor area SA. However, the disclosure is not limited thereto, and the first sensor electrodes SE1 may be sensing electrodes and the second sensor electrodes SE2 may be driving electrodes.

According to one or more embodiments, the sensing panel TSP may recognize the user's touch by sensing a change amount of a mutual capacitance formed between the first and second sensor electrodes SE1 and SE2.

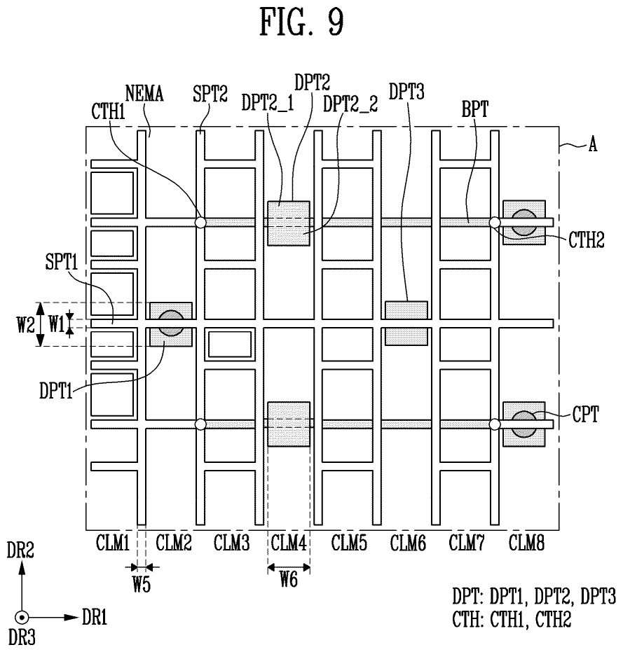

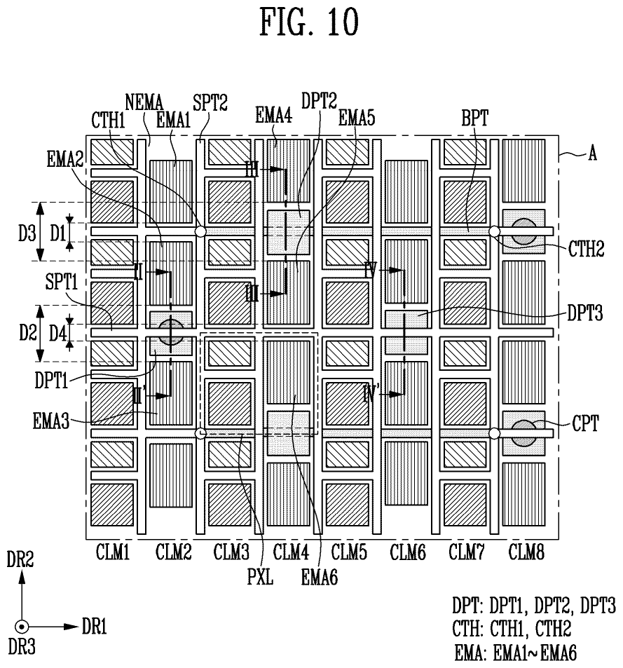

FIG. 9 is an enlarged view illustrating one or more embodiments of portion A of FIG. 8. FIG. 10 is an enlarged view illustrating one or more embodiments of portion A of FIG. 8 in the display device of FIG. 1. Compared to FIG. 9, more emission areas EMA1 to EMA6 are shown in FIG. 10.

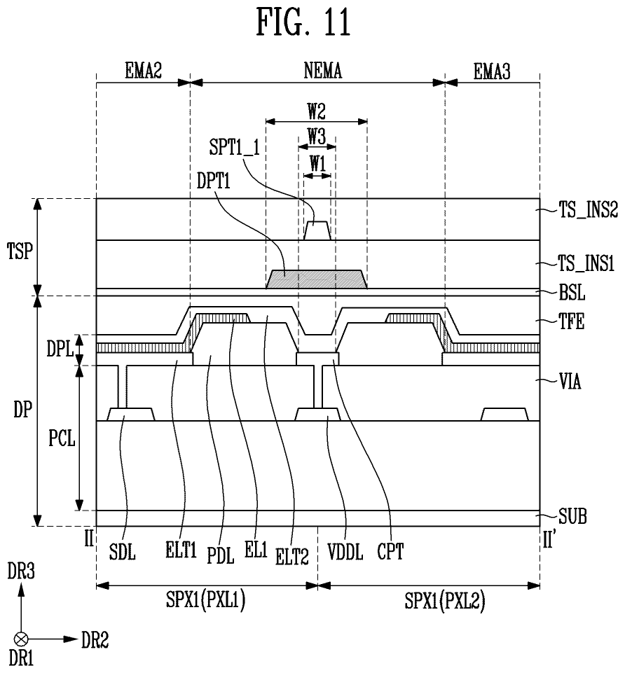

Referring to FIGS. 8 and 9, each of the plurality of sensor electrodes SE1 and SE2 may have sensor patterns overlapping the non-emission area NEMA. At this time, the non-emission area NEMA may refer to an area other than the emission areas EMA. For example, the non-emission area NEMA may overlap a pixel-defining layer (refer to PDL of FIG. 11). The sensor patterns may include first sensor patterns SPT1, second sensor patterns SPT2, a bridge pattern BPT, and at least one dummy pattern DPT.

The first sensor patterns SPT1 and the second sensor patterns SPT2 may be located in the same layer, and may be spaced apart from each other. The first and second sensor patterns SPT1 and SPT2 may be connected to each other at a corresponding point. The first and second sensor patterns SPT1 and SPT2 may be formed by the first conductive layer CPL1 (refer to FIG. 4).

The first sensor patterns SPT1 may extend in the first direction DR1, and may be spaced apart in the second direction DR2 crossing the first direction DR1. The first sensor patterns SPT1 may have a first width W1 in the second direction DR2. In addition, the second sensor patterns SPT2 may extend in the second direction DR2, and may be spaced apart in the first direction DR1. The second sensor patterns SPT2 may have a fifth width W5 in the first direction DR1. In one or more embodiments, the fifth width W5 may be the same width as the first width W1.

The bridge pattern BPT may extend in the first direction DR1, and may electrically connect the second sensor patterns SPT2, which are spaced apart from each other, to each other. The bridge pattern BPT may be located in a layer that is different from the first and second sensor patterns SPT1 and SPT2. For example, the bridge pattern BPT may be connected to one of the second sensor patterns SPT2 through a first contact hole CTH1, and may partially extend in a direction opposite to the third direction DR3. The bridge pattern BPT may be bent at a portion overlapping the first and second sensor patterns SPT1, SPT2, and may extend in the first direction. In addition, the bridge pattern BPT may partially extend in the third direction DR3 through a second contact hole CTH2, and may be connected to another of the second sensor patterns SPT2. Therefore, the bridge pattern BPT may extend in the first direction DR1, and may connect the second sensor patterns SPT2.

At least one dummy pattern DPT may be located in a layer that is different from the first and second sensor patterns SPT1 and SPT2. In addition, at least one dummy pattern DPT may be located in the same layer as the bridge pattern BPT. At least one dummy pattern DPT and the bridge pattern BPT may be formed by the second conductive layer CPL2, (refer to FIG. 4).

At least one dummy pattern DPT may have a second width W2 greater than the first width W1 in the second direction DR2, and may have a sixth width W6 greater than the fifth width W5 in the first direction DR1.

At least one dummy pattern DPT may overlap at least one of the first sensor patterns SPT1 or the bridge pattern BPT in a plan view. In embodiments, at least one dummy pattern DPT may be one of a first dummy pattern DPT1 overlapping a connection electrode CPT, a second dummy pattern DPT2 connected to a portion of the bridge pattern BPT, or a third dummy pattern DPT3 overlapping the first sensor patterns SPT1. According to one or more embodiments, the first to third dummy patterns DPT1 to DPT3 may have different widths. However, embodiments are not limited thereto, and the first to third dummy patterns DPT1 to DPT3 may have the same width.

The first dummy pattern DPT1 may be located in the non-emission area NEMA, and may overlap the connection electrode CPT configured to transmit the power voltage. That is, the connection electrode CPT may be located between the first power line VDDL and the first dummy pattern DPT1. In addition, the third dummy pattern DPT3 may overlap one of the first sensor patterns SPT1 extending in the first direction DR1. The first and third dummy patterns DPT1 and DPT3 may be electrically floated.

The second dummy pattern DPT2 may be connected to a portion of the bridge pattern BPT. In this case, the second dummy pattern DPT2 may include a first portion DPT2_1 protruding from the bridge pattern BPT in the second direction DR2, and a second portion DPT2_2 protruding from the bridge pattern BPT in a direction opposite to the second direction DR2. The second dummy pattern DPT2 may be connected to a portion of the bridge pattern BPT to electrically connect the second sensor patterns SPT2 to each other.

Referring to FIGS. 8 and 10, the first and second sensor patterns SPT1 and SPT2 may be formed in a mesh structure or a network structure in a plan view. The first and second sensor patterns SPT1 and SPT2 may surround the emission areas EMA of the sub-pixels forming the pixel PXL in a plan view. The first and second sensor patterns SPT1 and SPT2 may not overlap the emission areas EMA. In addition, the bridge pattern BPT and at least one dummy pattern DPT may not overlap the emission areas EMA. Therefore, the display device DD may reduce or prevent decrease of a luminance of light emitted from the emission areas EMA due to the sensing panel TSP.

According to one or more embodiments, the emission areas EMA may be arranged on the sub-pixel columns CLM1 to CLM8. In FIG. 10, the first to eighth sub-pixel columns CLM1 to CLM8 are shown as an example. However, this is for concise description and the display panel DP may include more sub-pixel columns. Each of the emission areas EMA may include a light-emitting element.

The first to eighth sub-pixel columns CLM1 to CLM8 may be arranged in the first direction DR1. The emission areas EMA of each of the first to eighth sub-pixel columns CLM1 to CLM8 may be arranged in the second direction DR2.

Emission areas that emit the same color light may be arranged in even-numbered sub-pixel columns CLM2, CLM4, CLM6, and CLM8. For example, emission areas for emitting green light may be arranged in the even-numbered sub-pixel columns CLM2, CLM4, CLM6, and CLM8. In this case, emission areas for emitting a color light that is different from that of the even-numbered sub-pixel columns CLM2, CLM4, CLM6, and CLM8 may be arranged in odd-numbered sub-pixel columns CLM1, CLM3, CLM5, and CLM7. For example, in the odd-numbered sub-pixel columns CLM1, CLM3, CLM5, and CLM7, emission areas for emitting red light and emission areas for emitting blue light may be alternately arranged.

Referring to FIG. 10, in each of the even-numbered sub-pixel columns CLM2, CLM4, CLM6, and CLM8, the emission areas EMA, and the non-emission area NEMA between the emission areas EMA, may be arranged to have relatively narrow distance and wide distance alternately. As an example, the second sub-pixel column CLM2 may include a first emission area EMA1, a second emission area EMA2, and a third emission area EMA3 arranged along the second direction DR2. The second emission area EMA2 may be spaced apart from the first emission area EMA1 by a first distance D1 in the second direction DR2. In addition, the third emission area EMA3 may be spaced apart from the second emission area EMA2 by a second distance D2 that is greater than the first distance D1 in the second direction DR2.

In addition, the fourth sub-pixel column CLM4 may include a fourth emission area EMA4, a fifth emission area EMA5, and a sixth emission area EMA6 arranged along the second direction DR2. The fifth emission area EMA5 may be spaced apart from the fourth emission area EMA4 by a third distance D3 in the second direction DR2. In addition, the sixth emission area EMA6 may be spaced apart from the fifth emission area EMA5 by a fourth distance D4 that is less than the third distance D3 in the second direction DR2. Here, the third distance D3 may be the same as the second distance D2, and the fourth distance D4 may be the same as the first distance D1, but are not limited thereto.

At least one of the first sensor patterns SPT1 or the bridge pattern BPT may be located between the first and second emission areas EMA1 and EMA2, between the second and third emission areas EMA2 and EMA3, between the fourth and fifth emission areas EMA4 and EMA5, and between the fifth and sixth emission areas EMA5 and EMA6. For example, the first sensor patterns SPT1 may extend in the first direction DR1 across the first and second emission areas EMA1 and EMA2, across the second and third emission areas EMA2 and EMA3, and across the fifth and sixth emission areas EMA5 and EMA6. The bridge pattern BPT may extend in the first direction DR1 across the fourth and fifth emission areas EMA4 and EMA5.

At least one dummy pattern DPT may be located between emission areas EMA arranged relatively distantly in a corresponding sub-pixel column. For example, the at least one dummy pattern DPT may be located between the second and third emission areas EMA2 and EMA3, and between the fourth and fifth emission areas EMA4 and EMA5 in a plan view. As described above, by locating at least one dummy pattern DPT in the non-emission area NEMA between the relatively distantly arranged emission areas EMA in the corresponding sub-pixel column, an optical visibility decrease according to recognition of the sensor patterns or the like may be reduced or prevented.

In the embodiments described above, the first and second sensor patterns SPT1 and SPT2 are included in the first conductive layer CPL1 (refer to FIG. 4), and at least one dummy pattern DPT and/or the bridge pattern BPT is included in the second conductive layer CPL2 (refer to FIG. 4) as an example, but the disclosure is not limited thereto. According to one or more embodiments, the first and second sensor patterns SPT1 and SPT2 may be included in the second conductive layer CPL2, and at least one dummy pattern DPT and/or the bridge pattern BPT may be included in the first conductive layer CPL1.

FIG. 11 is a cross-sectional view taken along the line II-II′ of FIG. 10.

Referring to FIGS. 10 and 11, each of first and second pixels PXL1 and PXL2 may include a first sub-pixel SPX1 including a light-emitting element emitting the same color light.

The first sub-pixel SPX1 included in the first pixel PXL1 may include the second emission area EMA2 that emits light, and the non-emission area NEMA that does not emit light. The first sub-pixel SPX1 included in the second pixel PXL2 may include the third emission area EMA3 that emits light and the non-emission area NEMA that does not emit light. Here, the second and third emission areas EMA2 and EMA3 may be emission areas that emit the same color light. In addition, the non-emission area NEMA may be located between the second and third emission areas EMA2 and EMA3.

The display panel DP may include the substrate SUB, the pixel circuit layer PCL provided and/or formed on the substrate SUB, and the display element layer DPL provided and/or formed on the pixel circuit layer PCL (as used herein, “formed on,” “provided on,” or “located on” may mean “above).

The first sub-pixel SPX1 included in each of the first and second pixels PXL1 and PXL2 may be provided on the substrate SUB, and may include the pixel circuit layer PCL including the pixel circuit SPC (refer to FIG. 6) including at least one transistor, the display element layer DPL provided on the pixel circuit layer PCL, and the thin layer encapsulation layer TFE.

In FIG. 11, for convenience, in the pixel circuit layer PCL, a via layer VIA and a source/drain electrode SDL of the transistor electrically connected to an anode electrode ELT1 located in the second emission area EMA2 are shown, but the pixel circuit layer PCL may also include a transistor and at least one insulating layer. For example, the transistor may include a semiconductor layer, a gate electrode, a source electrode, and a drain electrode, and may be formed of a thin film transistor.

The display element layer DPL may include the light-emitting elements, the connection electrode CPT, and a pixel-defining layer PDL. The light-emitting elements may include the anode electrodes ELT1, light-emitting layers EL1, and a cathode electrode ELT2.

The anode electrodes ELT1 may be located in the second and third emission areas EMA2 and EMA3, respectively. The light-emitting layers EL1 may be located on the anode electrodes ELT1, respectively. The second and third emission areas EMA2 and EMA3 may be emission areas for emitting green light. The second and third emission areas EMA2 and EMA3 may be defined as areas of the anode electrodes ELT1 exposed by an opening of the pixel-defining layer PDL, or as areas where the emission layers EL1 are located.

The connection electrode CPT may be located in the non-emission area NEMA in the same layer as the anode electrodes ELT1, and may be configured to transmit the power voltage. The connection electrode CPT may be located under the connection electrode CPT, and may be electrically connected to the first power line VDDL providing the power voltage. However, as the connection electrode CPT is formed, visibility may be decreased. For example, as the connection electrode CPT is formed in the non-emission area NEMA having a relatively wide distance, and the pixel-defining layer PDL is opened locally, visibility may be decreased.

Therefore, the first dummy pattern DPT1 may overlap the connection electrode CPT on the pixel-defining layer PDL. Through this, uniform visibility may be secured regardless of whether the pixel-defining layer PDL is opened, and a visibility decrease due to the connection electrode CPT may be reduced or prevented.

The pixel-defining layer PDL may locally cover the anode electrodes ELT1 and the connection electrode CPT. However, the pixel-defining layer PDL overlapping the connection electrode CPT may be locally opened. On the other hand, the pixel-defining layer PDL that does not overlap the connection electrode CPT may not be opened. The first and second sensor patterns SPT1 and SPT2 may be located on the pixel-defining layer PDL.

The cathode electrode ELT2 may be entirely located on the pixel-defining layer PDL, the light-emitting layers EL1, and the connection electrode CPT. The cathode electrode ELT2 may be electrically connected to the light-emitting layers EL1 and the connection electrode CPT.

The thin layer encapsulation layer TFE may be provided and/or formed on the display element layer DPL. The sensing panel TSP may be provided and/or formed on the thin layer encapsulation layer TFE.

The sensing panel TSP may include the first and second sensor patterns SPT1 and SPT2, the bridge pattern BPT, at least one dummy pattern DPT, and first and second insulating layers TS_INS1 and TS_INS2 located on the base layer BSL.

According to one or more embodiments, the first dummy pattern DPT1 may be located between a first sensor pattern SPT1_1 and the display panel DP. The first dummy pattern DPT1 may be located between the first sensor pattern SPT1_1 and the connection electrode CPT. In addition, the first dummy pattern DPT1 may overlap the first sensor pattern SPT1_1 and the connection electrode CPT. That is, the first dummy pattern DPT1 may be located in the non-emission area NEMA between the second and third emission areas EMA2 and EMA3 together with the first sensor pattern SPT1_1 and the connection electrode CPT.

Referring to FIG. 11, the first dummy pattern DPT1 may have a width that is different from each of the first sensor pattern SPT1_1 and the connection electrode CPT overlapping the first dummy pattern DPT1. As an example, the first sensor pattern SPT1_1 may have a first width W1 in the second direction DR2. The connection electrode CPT may have a third width W3 that is greater than the first width W1 in the second direction DR2. In this case, the first dummy pattern DPT1 may have a second width W2 that is greater than the first width W1 of the first sensor pattern SPT1_1 in the second direction DR2. In addition, the second width W2 of the first dummy pattern DPT1 may be greater than the third width W3 of the connection electrode CPT. However, the second width W2 of the first dummy pattern DPT1 may be set to a width within a range that does not block viewing angles of the sub-pixels between the second and third emission areas EMA2 and EMA3.

As described above, by forming the first dummy pattern DPT1, which has a width that is greater than that of the connection electrode CPT, on the connection electrode CPT, a light reflection amount by the connection electrode CPT may be reduced, thereby further improving visibility of a screen.

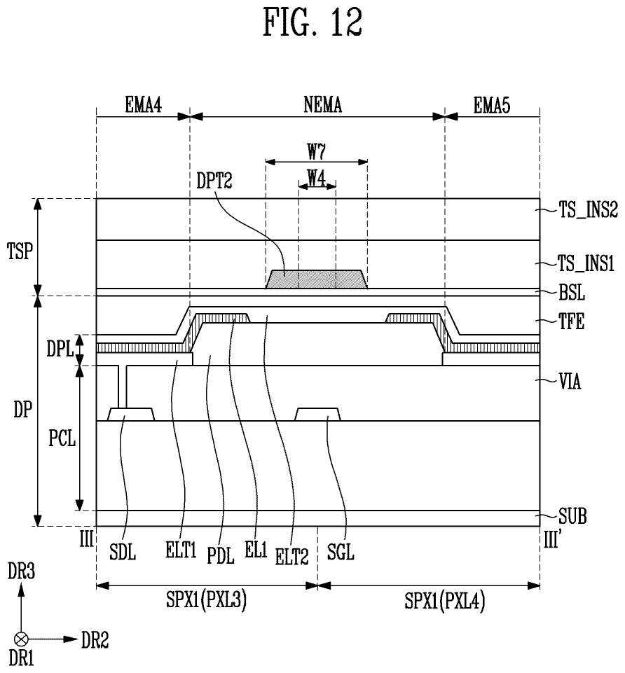

FIG. 12 is a cross-sectional view taken along the line III-III′ of FIG. 10.

Each of configurations of the display device DD may be configured similarly to the embodiments of FIG. 11 described above.

Referring to FIGS. 10 and 12, the second dummy pattern DPT2 may be located on the pixel-defining layer PDL. Except for this, third and fourth pixels PXL3 and PXL4 may have a configuration substantially identical or similar to that of the first and second pixels PXL1 and PXL2 shown in FIG. 11. For example, the first sub-pixel SPX1 included in each of the third and fourth pixels PXL3 and PXL4 may be provided on the substrate SUB, and may include the pixel circuit layer PCL, the display element layer DPL provided on the pixel circuit layer PCL, and the thin layer encapsulation layer TFE. Hereinafter, a description overlapping FIG. 11 is omitted.

Each of the third and fourth pixels PXL3 and PXL4 may include the first sub-pixel SPX1 including the light-emitting element emitting the same color light.

The first sub-pixel SPX1 included in the third pixel PXL3 may include the fourth emission area EMA4 that emits light, and the non-emission area NEMA that does not emit light. The first sub-pixel SPX1 included in the fifth pixel PXL5 may include the fifth emission area EMA5 that emits light, and the non-emission area NEMA that does not emit light. Here, the fourth and fifth emission areas EMA4 and EMA5 may be emission areas for emitting the same color light.

According to one or more embodiments, the second dummy pattern DPT2 may be located on the pixel-defining layer PDL. The second dummy pattern DPT2 may overlap the pixel-defining layer PDL without overlapping the light-emitting layers EL1. The pixel-defining layer PDL overlapping the second dummy pattern DPT2 may be a pixel-defining layer located in the non-emission area NEMA between the fourth and fifth emission areas EMA4 and EMA5. In addition, the second dummy pattern DPT2 may also overlap a signal line SGL located under the pixel-defining layer PDL.

The second dummy pattern DPT2 may include a first portion DPT2_1 (refer to FIG. 9) protruding from the bridge pattern BPT in the second direction DR2, and a second portion DPT2_2 (refer to FIG. 9) protruding in a direction that is opposite to the second direction DR2. The second dummy pattern DPT2 may have a width that is different from that of the bridge pattern BPT connected to the second dummy pattern DPT2. For example, a portion of the bridge pattern BPT may be connected to the first and second portions DPT2_1 and DPT2_2 of the second dummy pattern DPT2. The second dummy pattern DPT2 may be connected to a portion of the bridge pattern BPT and may have a seventh width W7 in the second direction DR2. On the other hand, a remainder of the bridge pattern BPT that is not connected to the second dummy pattern DPT2 may have a fourth width W4 that is less than the seventh width W7 in the second direction DR2. However, the seventh width W7 of the second dummy pattern DPT2 may be set to a width within a range that does not block a viewing angle of the sub-pixels between the fourth and fifth emission areas EMA4 and EMA5.

Referring to FIGS. 11 and 12, the seventh width W7 of the second dummy pattern DPT2 may be greater than the second width W2 of the first dummy pattern DPT1. As an example, a width of each of the first and second dummy patterns DPT1 and DPT2 may be set to have the same reflectance in the corresponding non-emission area NEMA. For example, the first dummy pattern DPT1 may overlap the first sensor pattern SPT1_1 and the connection electrode CPT, and may be located in an area where a portion of the pixel-defining layer PDL is opened. On the other hand, the second dummy pattern DPT2 may be located in an area overlapping the pixel-defining layer PDL. An area where the second dummy pattern DPT2 is located may also overlap the signal line SGL. Accordingly, a reflectance difference may occur in an area where the first and second dummy patterns DPT1 and DPT2 are located. Accordingly, by forming the first and second dummy patterns DPT1 and DPT2 at different widths, the first and second dummy patterns DPT1 and DPT2 may be adjusted to have a generally uniform reflectance.

As described above, by forming the second dummy pattern DPT2 having a width that is greater than that of the bridge pattern BPT on the pixel-defining layer PDL, a reflectance amount of light due to the pixel-defining layer PDL (and the signal line SGL located under the pixel-defining layer PDL), visibility of the screen may be improved. In addition, because the second dummy pattern DPT2 may be connected to the bridge pattern BPT, the bridge pattern BPT may be expanded.

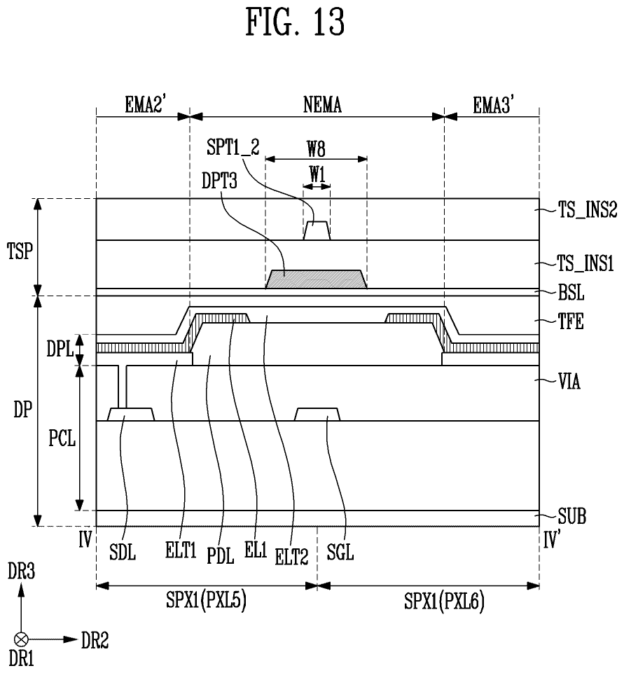

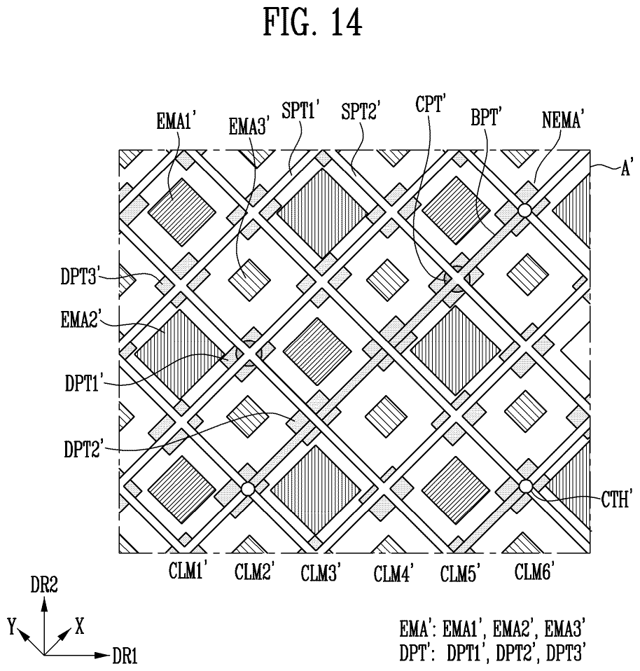

FIG. 13 is a cross-sectional view taken along the line IV-IV′ of FIG. 10.

Each of configurations of the display device DD may be configured similarly to the embodiments of FIG. 11 described above.

Referring to FIGS. 10 and 13, the third dummy pattern DPT3 may be located on the pixel-defining layer PDL, and may overlap the first sensor pattern SPT1. Except for this, fifth and sixth pixels PXL5 and PXL6 may have a configuration substantially identical or similar to that of the first and second pixels PXL1 and PXL2 shown in FIG. 11. For example, the first sub-pixel SPX1 included in each of the fifth and sixth pixels PXL5 and PXL6 may be provided on the substrate SUB, and may include the pixel circuit layer PCL, the display element layer DPL provided on the pixel circuit layer PCL, and the thin layer encapsulation layer TFE. Hereinafter, a description overlapping FIG. 11 is omitted.

Each of the fifth and sixth pixels PXL5 and PXL6 may include the first sub-pixel SPX1 including the light-emitting element emitting the same color light.

The first sub-pixel SPX1 included in the fifth pixel PXL5 may include second emission areas EMA2′ that emit light, and the non-emission area NEMA that does not emit light. The first sub-pixel SPX1 included in the sixth pixel PXL6 may include a third emission area EMA3′ that emits light, and the non-emission area NEMA that does not emit light. Here, the second and third emission areas EMA2′ and EMA3′ may be emission areas for emitting the same color light.

According to one or more embodiments, the third dummy pattern DPT3 may be located on the pixel-defining layer PDL. The third dummy pattern DPT3 may overlap a first sensor pattern SPT1_2. The third dummy pattern DPT3 may overlap the pixel-defining layer PDL without overlapping the light-emitting layers EL1. The pixel-defining layer PDL overlapping the third dummy pattern DPT3 may be a pixel-defining layer located in the non-emission area NEMA between the second and third emission areas EMA2′ and EMA3′. In addition, the third dummy pattern DPT3 may also overlap the signal line SGL located under the pixel-defining layer PDL.

The third dummy pattern DPT3 may be located between the first sensor pattern SPT1_2 and the display panel DP. The third dummy pattern DPT3 may be located between the first sensor pattern SPT1_2 and the signal line SGL. The third dummy pattern DPT3 may be located in the non-emission area NEMA between the second and third emission areas EMA2′ and EMA3′ together with the first sensor pattern SPT1_2 and the signal line SGL.

Referring to FIG. 13, the third dummy pattern DPT3 may have a width that is different from that of the first sensor pattern SPT1_2 overlapping the third dummy pattern DPT3. As an example, the first sensor pattern SPT1_2 may have a first width W1 in the second direction DR2. The third dummy pattern DPT3 may have an eighth width W8 that is greater than the first width W1 of the first sensor pattern SPT1_2 in the second direction DR2. In addition, the eighth width W8 of the third dummy pattern DPT3 may be greater than a width of the signal line SGL. However, the eighth width W8 of the third dummy pattern DPT3 may be set to a width within a range that does not block viewing angles of sub-pixels between the second and third emission areas EMA2′ and EMA3′.

As described above, by forming the third dummy pattern DPT3 having a width that is greater than that of the first sensor pattern SPT1_2 on the pixel-defining layer PDL, a reflectance amount of light due to the pixel-defining layer PDL and the signal line SGL located under the pixel-defining layer PDL may be decreased, thereby improving visibility of the screen.

Referring to FIGS. 11, 12, and 13, the eighth width W8 of the third dummy pattern DPT3 may be greater than the second width W2 of the first dummy pattern DPT1. In addition, the eighth width W8 of the third dummy pattern DPT3 may be less than the seventh width W7 of the second dummy pattern DPT2. As an example, a width of each of the first to third dummy patterns DPT1 to DPT3 may be set to have the same reflectance in the corresponding non-emission area NEMA. For example, the first dummy pattern DPT1 may overlap the first sensor pattern SPT1_1 and the connection electrode CPT, and may be located in an area where a portion of the pixel-defining layer PDL is opened. The second dummy pattern DPT2 may be located in an area overlapping the pixel-defining layer PDL and the signal line SGL without overlapping the first sensor patterns SPT1. In addition, the third dummy pattern DPT3 may be located in an area overlapping the first sensor pattern SPT1_2 and the signal line SGL. Accordingly, a reflectance difference may occur in an area where the first to third dummy patterns DPT1 to DPT3 are located.

As described above, the first to third dummy patterns DPT1 to DPT3 may be located at different widths. Through this, a uniform reflectance may be implemented regardless of whether the connection electrode CPT, the signal line SGL, and the sensor patterns are located, and whether the pixel-defining layer PDL is opened. Therefore, an optical visibility decrease due to a reflectance difference or the like may be reduced or prevented.

FIG. 14 is an enlarged view illustrating one or more other embodiments of portion A of FIG. 8.

First sensor patterns SPT1′, second sensor patterns SPT2′, a bridge pattern BPT′, at least one dummy pattern DPT′, a connection electrode CPT′, and a contact hole CTH+ may be described similarly to the embodiments of FIG. 10. An overlapping or repetitive description with respect to the embodiments of FIG. 10 is omitted, and a point that is different from the embodiments described above is mainly described.

Referring to FIG. 14, the first sensor patterns SPT1′ may extend in an X-axis direction, and may be spaced apart in a Y-axis direction crossing the X-axis direction. The second sensor patterns SPT2′ may extend in the Y-axis direction, and may be spaced apart in the X-axis direction. The second sensor patterns SPT2′ may be located in the same layer as the first sensor patterns SPT1′, and may be connected to the first sensor patterns SPT1′.

The bridge pattern BPT′ may extend in the X-axis direction, and may electrically connect the second sensor patterns SPT2′, which are spaced apart from each other, to each other. The bridge pattern BPT′ may be located in a layer that is different from the first and second sensor patterns SPT1′ and SPT2′. The bridge pattern BPT′ may extend in the X-axis direction, and may connect the second sensor patterns SPT2′.

The first and second sensor patterns SPT1′ and SPT2′ may be formed in a mesh structure or a network structure in a plan view. The first and second sensor patterns SPT1′ and SPT2′ may surround emission areas EMA′ of each of the sub-pixels forming the pixel in a plan view. At this time, each of the sub-pixels may be arranged in a diamond structure.

According to one or more embodiments, the emission areas EMA′ may be arranged on sub-pixel columns CLM1′ to CLM6′. The first to sixth sub-pixel columns CLM1′ to CLM6′ may be arranged in the first direction DR1. Each of the first to sixth sub-pixel columns CLM1′ to CLM6′ may extend in the second direction DR2. At this time, the first direction DR1 may be a diagonal direction in which the X-axis direction and a direction opposite to the Y-axis cross, and the second direction DR2 may be a diagonal direction in which the X-axis direction and the Y-axis direction cross.

Third emission areas EMA3′ emitting the same color light may be arranged in even-numbered sub-pixel columns CLM2′, CLM4′, CLM6′, and CLM8′. On the other hand, emission areas for emitting color light that is different from that of the even-numbered sub-pixel columns CLM2′, CLM4′, and CLM6′ may be arranged in odd-numbered sub-pixel columns CLM1′, CLM3′, and CLM5′. For example, the first emission areas EMA1′ and the second emission areas EMA2′ may be alternately arranged in the odd-numbered sub-pixel columns CLM1′, CLM3′, and CLM5′. In this case, the third emission areas EMA3′ may be arranged to be spaced apart from each other in the first and second directions DR1 and DR2. The first emission areas EMA1′ or the second emission areas EMA2′ may be arranged adjacent to the third emission areas EMA3′ in the X-axis direction or the Y-axis direction.

Referring to FIG. 10, at least one dummy pattern DPT′ may be located between neighboring emission areas EMA′ of each of the first to sixth sub-pixel columns CLM1′ to CLM6′. In each of the first to sixth sub-pixel columns CLM1′ to CLM6′, at least one dummy pattern DPT′ may be arranged in the non-emission area NEMA′ between the emission areas EMA′. For example, at least one dummy pattern DPT′ may be arranged in each non-emission area NEMA′ between neighboring third emission areas EMA3′.

At least one dummy pattern DPT′ may overlap at least one of points where the first and second sensor patterns SPT1′ and SPT2′ cross and/or points where the bridge pattern BPT′ and the second sensor patterns SPT2 cross, in a plan view.

In embodiments, at least one dummy pattern DPT′ may be one of a first dummy pattern DPT1′ overlapping the connection electrode CPT′, a second dummy pattern DPT2′ connected to a portion of the bridge pattern BPT′, or a third dummy pattern DPT3′ overlapping the first sensor patterns SPT1′. The first to third dummy patterns DPT1′ to DPT3′ may be described similarly to the embodiments of FIGS. 11 to 13. An overlapping description with respect to the embodiments of FIGS. 11 to 13 is omitted.

In the display device according to embodiments of the disclosure, by locating at least one dummy pattern DPT in the non-emission area NEMA between the emission areas EMA arranged relatively distantly in the corresponding sub-pixel column, an optical visibility decrease due to recognition of the sensor patterns or the like may be reduced or prevented. For example, according to embodiments of the disclosure, when at least one dummy pattern DPT is located on the pixel-defining layer PDL to overlap the connection electrode CPT, uniform visibility may be secured regardless of whether the pixel-defining layer PDL is opened, and a visibility decrease due to the connection electrode CPT may be reduced or prevented.

Although specific embodiments and applications are described herein, other embodiments and variations may be derived from the above description. Therefore, the spirit of the disclosure is not limited to these embodiments, and extends to the scope of the claims set forth below, various obvious modifications, and equivalents.

According to embodiments of the disclosure, a display device with improved reliability is provided.

An effect according to embodiments is not limited to the content exemplified above, and further various effects are included in the present specification.

What is claimed is:

1. A display device comprising:
a display panel comprising emission areas, and a non-emission area between the emission areas; and
a sensing panel above the display panel, and having sensor patterns overlapping the non-emission area and comprising:
first sensor patterns extending in a first direction, spaced apart in a second direction crossing the first direction, and having a first width in the second direction;
second sensor patterns at a same layer as the first sensor patterns, connected to the first sensor patterns, extending in the second direction, and spaced apart in the first direction; and
at least one dummy pattern at a layer that is different from the first and second sensor patterns, and having a second width that is greater than the first width in the second direction.

2. The display device according to claim 1, wherein the display panel comprises:
anode electrodes in the emission areas; and
a connection electrode in the non-emission area at a same layer as the anode electrodes, configured to transmit a power voltage, and overlapping the at least one dummy pattern.

3. The display device according to claim 2, wherein the display panel further comprises a power line under the connection electrode, configured to provide the power voltage, and electrically connected to the connection electrode, and
wherein the connection electrode is between the power line and the at least one dummy pattern.

4. The display device according to claim 2, wherein the connection electrode has a third width that is less than the second width in the second direction.

5. The display device according to claim 4, wherein the third width is greater than the first width.

6. The display device according to claim 2, wherein the display panel comprises:
a pixel-defining layer partially covering the anode electrodes and the connection electrode;
light-emitting layers respectively above the anode electrodes; and
a cathode electrode entirely above the pixel-defining layer, the light-emitting layers, and the connection electrode, and electrically connected to the connection electrode and to the light-emitting layers.

7. The display device according to claim 1, wherein the sensor patterns further comprise a bridge pattern at a same layer as the at least one dummy pattern, extending in the first direction, and electrically connecting the second sensor patterns to each other.

8. The display device according to claim 7, wherein the at least one dummy pattern comprises a first portion protruding from the bridge pattern in the second direction, and a second portion protruding in a direction opposite to the second direction.

9. The display device according to claim 8, wherein the first portion, the second portion, and a portion of the bridge pattern connected to the first and second portions have the second width in the second direction.

10. The display device according to claim 9, wherein the bridge pattern has a fourth width that is less than the second width in the second direction.

11. The display device according to claim 7, wherein the bridge pattern is at a layer that is different from a layer in which the second sensor patterns are located.

12. The display device according to claim 7, wherein the emission areas comprise:
a first column of ones of the emission areas arranged along the second direction, and comprising:
a first emission area;
a second emission area spaced apart from the first emission area by a first distance in the second direction; and
a third emission area spaced apart from the second emission area by a second distance that is greater than the first distance in the second direction; and
a second column of others of the emission areas arranged along the second direction, and
wherein the at least one dummy pattern is between the second and third emission areas in a plan view.

13. The display device according to claim 12, wherein the second column of the others of the emission areas comprises:
a fourth emission area;
a fifth emission area spaced apart from the fourth emission area by a third distance in the second direction; and
a sixth emission area spaced apart from the fifth emission area by a fourth distance that is less than the third distance in the second direction, and
wherein the bridge pattern extends in the first direction across the fourth and fifth emission areas, and has the second width between the fourth and fifth emission areas.

14. The display device according to claim 13, wherein the first column of the ones of the emission areas, and the second column of the others of the emission areas, are configured to emit a same color light.

15. The display device according to claim 1, wherein the at least one dummy pattern overlaps one of the first sensor patterns.

16. The display device according to claim 1, wherein the at least one dummy pattern is electrically floated.

17. The display device according to claim 1, wherein the second sensor patterns have a fifth width in the first direction, and
wherein the at least one dummy pattern has a sixth width that is greater than the fifth width in the first direction.

18. The display device according to claim 17, wherein the fifth width is substantially equal to the first width.

19. The display device according to claim 1, wherein the emission areas are arranged in columns defined along a diagonal direction crossing the first and second directions, and
wherein the at least one dummy pattern is between neighboring ones of the emission areas of the columns.
